(19) United States
(12) Patent Application Publication
(10) Pub. No.: US 2006/0108613 A1
(43) Pub. Date: May 25, 2006

(54) CMOS image sensor

(76) Inventors: Young Joo Song, Daejeon (KR); Bong Ki Mheen, Daejeon (KR); Jin Yeong Kang, Daejeon (KR)

Correspondence Address: LADAS & PARRY LLP, 224 SOUTH MICHIGAN AVENUE, SUITE 1600, CHICAGO, IL, 60604, US

(21) Appl. No.: 11/166,639

(22) Filed: Jun. 24, 2005

(30) Foreign Application Priority Data
Nov. 25, 2004 (KR) 2004-97659

(51) Int. Cl. H01L 27/148

(52) U.S. Cl. 257/233

(57) ABSTRACT

Provided is a CMOS image sensor including a pinned photodiode and a transfer transistor. The CMOS image sensor includes: a substrate; a gate electrode disposed on the substrate and electrically isolated from the substrate by a gate insulating layer; a first floating region disposed in the substrate of one side of the gate electrode; a first impurity region for a photodiode disposed in the substrate of the other side of the gate electrode; a second floating region disposed in the substrate between the first impurity region for the photodiode and the gate electrode; and a second impurity region for the photodiode disposed in a surface portion of the substrate including the first impurity region for the photodiode and the second floating region.

### CROSS-REFERENCE TO RELATED APPLICATION

This application claims priority to and the benefit of Korean Patent Application No. 2004-97659, filed Nov. 25, 2004, the disclosure of which is incorporated herein by reference in its entirety.

### BACKGROUND

1. Field of the Invention

The present invention relates to a complementary metal oxide semiconductor (CMOS) image sensor and, more specifically, to a CMOS image sensor including a pinned photodiode and a transfer transistor.

2. Discussion of Related Art

In general, a CMOS image sensor is a semiconductor device that converts optical images into electric signals and is composed of a photodiode and a circuit block for processing signals.

FIG. 1 is a schematic circuit diagram of a typical CMOS image sensor. Referring to FIG. 1, the CMOS image sensor includes a photodiode 1, a transfer transistor 2, a reset transistor 4, a drive transistor 5, a select transistor 6, and a load transistor 7. The photodiode 1 produces photo-carriers in response to optical images, and the transfer transistor 2 transfers the photo-carriers to a floating diffusion region 3. The reset transistor 4 performs a reset operation of exhausting the photo-carriers from the floating diffusion region 3 by adjusting the electric potential of the floating diffusion region 3 to a desired value. The drive transistor 5 acts as a buffer amplifier. The select transistor 6 is used for an addressing operation, and the load transistor 7 is used to read output signals.

The above-described CMOS image sensor can be fabricated using well-developed CMOS fabrication techniques and enables a number of circuit blocks to be integrated on a single substrate, in comparison to a charge-coupled device (CCD) that is widely used for a conventional image sensor. Also, in terms of power consumption, which is the first consideration for mobile electronic devices, the CMOS image sensor is even more excellent than the CCD so that it has attracted much attention as the next-generation image sensor.

Nevertheless, the CMOS image sensor is estimated to be less efficient than the CCD because of several problems. A low performance of the CMOS image sensor arises from a low signal-to-noise ratio (SNR) and a low dynamic range (DR), and the distribution of the SNR and DR among pixels or wafers is unstable to cause low image quality in the CMOS image sensor.

In order to improve the SNR and DR, a pixel (esp., the photodiode 1 and the transfer transistor 2) need to be structurally optimized and its fabrication process should be stabilized. Conventional methods for attaining the structural optimization of the pixel were aimed to minimize a dark current caused by defects by increasing the sensitivity and capacitance of the photodiode. Above all, a pinned photodiode, of which surface is covered with a heavily doped p-type impurity region, can increase the depth of a depletion region and isolate surface defects, thus it is being commonly utilized nowadays.

FIG. 2 is a cross-sectional view of a conventional CMOS image sensor, and FIG. 3 illustrates a layout of the conventional CMOS image sensor shown in FIG. 2. Here, FIG. 3 mainly illustrates the photodiode 1 and the transfer transistor 2 shown in FIG. 1.

A gate insulating layer 12 and a gate electrode 13 are stacked on a substrate 10 at which a trench-type isolation layer 11 is formed. Spacers 14 are formed on both sidewalls of the gate electrode 13. A floating drain region 15 is formed in the substrate 10 of one side of the gate electrode 13, and an n-type impurity region 16 for a photodiode is formed in the substrate 10 of the other side of the gate electrode 13. A shallow p-type impurity region 17 for a photodiode is formed on a surface of the n-type impurity region 16 for the photodiode.

In the above conventional structure of the CMOS image sensor, since a portion that connects the photodiode 1 and the transfer transistor 2 (hereinafter, a connection portion) is extremely unstable, there is a high likelihood that charge transfer efficiency becomes low according to the impurity-concentration profile of the n-type impurity region 16 and the impurity diffusion extent of the p-type impurity region 17. Also, a variance in the distribution of impurities in pixels or wafers is relatively large.

The charge transfer efficiency is a significant parameter that is closely associated with the SNR and DR of an image sensor. The charge transfer efficiency is preferably as high as possible and should have errors in a very small range among pixels or wafers. The p-type impurity region 17 formed on the surface of the n-type impurity region 16 is heavily doped with impurities to cause a pinning effect. As a result, the impurities are diffused in a subsequent annealing process so that the impurity-concentration profile of the p-type impurity region 17 cannot be held constant. For example, when a subsequent excessive annealing process permits the heavily doped p-type impurity region 17 to be disposed between a channel of the transfer transistor and the n-type impurity region 16 for the photodiode, the possibility of complete depletion of the p-type impurity region 17 between a channel of the transfer transistor and the n-type impurity region 16 becomes low. Hence, the p-type impurity region 17 operates like a base of an NPN type bipolar transistor, and the charge transfer efficiency may be seriously degraded. If the charge transfer efficiency of the connection portion is modulated by light, a signal gain is obtained in the pixel so that the SNR and DR can be notably improved. However, since the conventional structure includes the connection portion covered with a gate of the transfer transistor, light is hardly incident on the connection portion to ensure only an immaterial signal gain. Therefore, these problems lead to a strong need for a new structure that can improve charge transfer efficiency, signal gain, and process margin.

### SUMMARY OF THE INVENTION

The present invention is directed to a CMOS image sensor including a pinned photodiode, which can improve charge transfer efficiency and a signal gain and reduce the variance of the characteristics among pixels or wafers so that the CMOS image sensor can have better performance.

One aspect of the present invention is to provide a CMOS image sensor including: a substrate; a gate electrode disposed on the substrate and electrically isolated from the substrate by a gate insulating layer; a first floating region disposed in the substrate of one side of the gate electrode; a first impurity region for a photodiode disposed in the substrate of the other side of the gate electrode; a second floating region disposed in the substrate between the first impurity region for the photodiode and the gate electrode; and a second impurity region for the photodiode disposed in a surface portion of the substrate including the first impurity region for the photodiode and the second floating region.

The first impurity region for the photodiode may be spaced a predetermined distance apart from the second floating region.

The CMOS image sensor may further include a third impurity region disposed in the substrate between the first impurity region for the photodiode and the second floating region.

The third impurity region may be disposed in a lateral surface of the first impurity region for the photodiode, and the third impurity region may have a depth equal to the second floating region.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 is a circuit diagram of a typical CMOS image sensor;

FIG. 2 is a cross-sectional view of a conventional CMOS image sensor;

FIG. 3 illustrates a layout of the conventional CMOS image sensor shown in FIG. 2;

FIG. 4 is a cross-sectional view of a CMOS image sensor according to an exemplary embodiment of the present invention;

FIG. 5 is a cross-sectional view of a CMOS image sensor according to another exemplary embodiment of the present invention; and

FIG. 6 illustrates a layout of the CMOS image sensors shown in FIGS. 4 and 5.

### DETAILED DESCRIPTION OF EXEMPLARY EMBODIMENTS

The present invention will now be described more fully hereinafter with reference to the accompanying drawings, in which exemplary embodiments of the invention are shown. This invention may, however, be embodied in different forms and should not be construed as limited to the embodiments set forth herein. Rather, these embodiments are provided so that this disclosure is thorough and complete and fully conveys the scope of the invention to those skilled in the art.

According to the present invention, in a CMOS image sensor including a pinned photodiode and a transfer transistor, a portion that connects a source of the transfer transistor and the pinned photodiode (hereinafter, a connection portion) is structurally modified in order to improve charge transfer efficiency and a signal gain and greatly reduce the variance of the characteristics among pixels or wafers.

FIG. 4 is a cross-sectional view of a CMOS image sensor according to an exemplary embodiment of the present invention. The CMOS image sensor will be described with reference to FIG. 6, which mainly illustrates a photodiode and a transfer transistor.

A gate insulating layer 42 and a gate electrode 43 are stacked on a substrate 40 at which a trench-type isolation layer 41 is formed, and spacers 44 are formed on both sides of the gate electrode 43. A floating drain region 45 is formed in the substrate 40 of one side of the gate electrode 43, and an n-type impurity region 46 for a photodiode is formed in the substrate 40 of the other side of the gate electrode 43. A floating source region 48 is formed in the substrate 40 between the n-type impurity region 46 for the photodiode and the gate electrode 43. A p-type impurity region 47 for a pinning effect is formed in a surface portion of the substrate 40 including the n-type impurity region 46 for the photodiode and the floating source region 48.

The n-type impurity region 46 for the photodiode is spaced a predetermined distance apart from the floating source region 48. The floating drain region 45 and the floating source region 48 are doped with impurities of the same conductivity type, for example, they are heavily doped with n-type impurities.

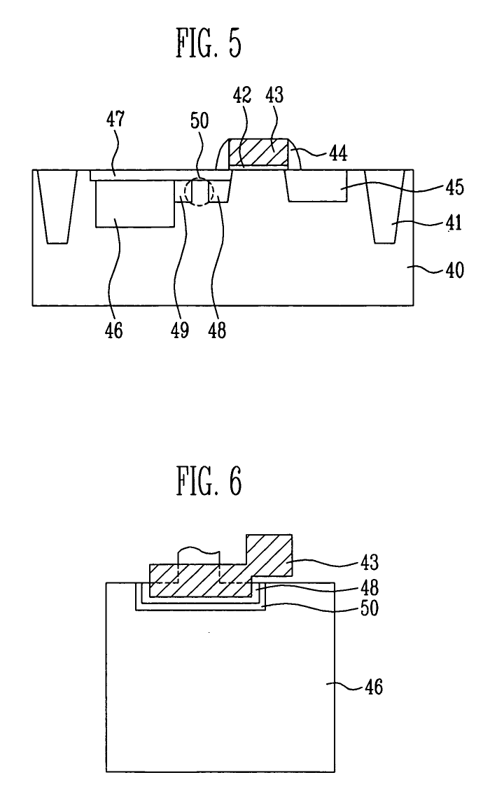

FIG. 5 is a cross-sectional view of a CMOS image sensor according to another exemplary embodiment of the present invention. An additional n-type impurity region 49 is formed adjacent to the n-type impurity region 46 for the photodiode in the structure shown in FIG. 4. The n-type impurity region 49 serves to define a transfer path of charge carriers produced from the n-type impurity region 46 for the photodiode. The n-type impurity region 49 is disposed in the lateral surface of the n-type impurity region 46 for the photodiode in a direction of the floating source region 48. The n-type impurity region 49 is formed to a depth equal to the floating source region 48 so that the charge carriers are transferred by a constant electric field. When the charge carriers are transferred by the constant electric field, charge transfer efficiency can be easily modulated and the variance of the characteristics among pixels or wafers can be greatly reduced.

As described above, according to the present invention, the floating source region 48 is formed in the substrate 40 between the n-type impurity region 46 for the photodiode and the gate electrode 43. Further, the n-type impurity region 49 is formed in the lateral surface of the n-type impurity region 46 for the photodiode to a depth equal to the floating source region 48. Hence, the following effects can be obtained.

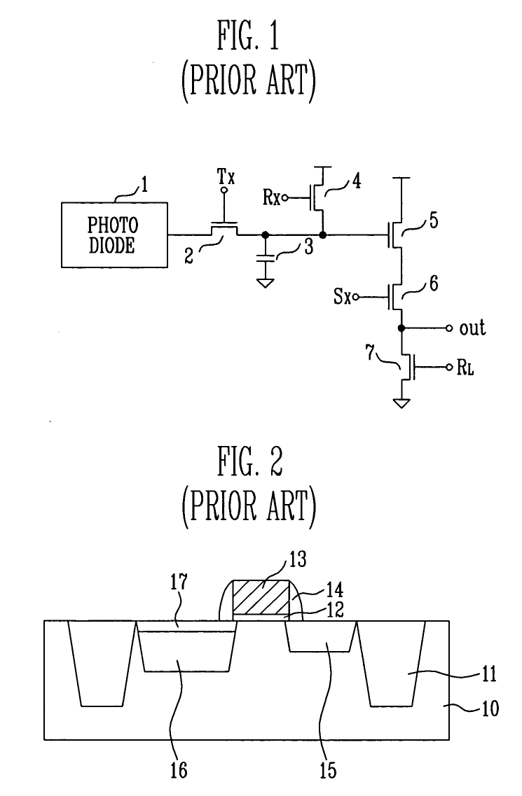

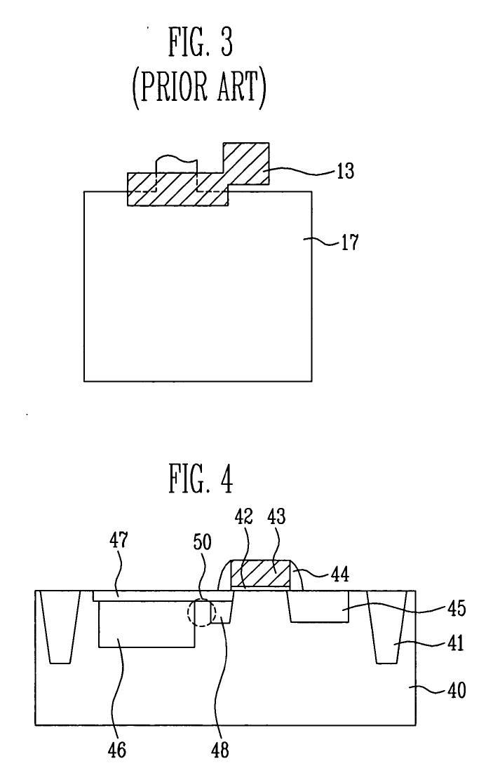

First, the charge transfer efficiency can be enhanced while photo-carriers produced from a photodiode are being transferred through a transfer transistor to a floating diffusion region. The charge transfer efficiency becomes uniform among pixels or wafers. Specifically, because when the transfer transistor is turned on, the electric potential of a channel becomes relatively high, the photo-carriers (i.e., electrons) produced from the photodiode tend to move toward the channel of the transfer transistor. At this time, the distribution of impurities and the topological structure of a connection portion between the photodiode and the transfer transistor determine the charge transfer efficiency. For the distribution of impurities, it is preferable that a completely depleted p-type region be present between the n-type impurity region 46 for the photodiode and an n-type channel of the transfer transistor. As a result, the photo-carriers do not combine with each other in the p-type impurity region but remain intact due to a strong electric field and are transferred to the channel of the transfer transistor. If the area of the p-type impurity region is non-uniform or if there is a large variance in the distribution of impurities, the charge transfer efficiency may vary within a large range. Also, when there is a variance in the distribution of impurities in the depth direction in the topological structure of the connection portion, since the charge transfer efficiency is determined in a 3-dimensional manner by the electric potential and the distribution of impurities, it is difficult to maintain the charge transfer efficiency at a constant high level. In this respect, for the conventional structure shown in FIG. 2, photo-carriers produced from the pinned photodiode are directly transferred to the channel of the transfer transistor disposed under the gate insulating layer. However, in the conventional structure, since the shape of the channel is susceptible to the electrical and topological states of the gate insulating layer, the gate electrode, the spacers, and the semiconductor substrate, a variance in charge transfer efficiency is relatively large and the charge transfer efficiency itself is relatively low. Also, as the depth of the n-type impurity region 16 for the pinned photodiode depends on the depth of the p-type impurity region 17 formed in the surface portion of the photodiode, the connection portion between the photodiode and the transfer transistor has a 3-dimensional shape that is affected by the variance in charge transfer efficiency in the depth direction. Thus, the connection portion becomes far more susceptible. However, the present invention provides the floating region 48, which is formed at a source of the transfer transistor. Thus, the connection portion between the photodiode and the transfer transistor has a 2-dimensional shape, in which charge transfer efficiency is irrelevant to the shape of the channel of the transfer transistor and the depth of the p-type impurity region 47 formed in the surface portion of the photodiode. In addition, the CMOS image sensor of the present invention includes a very deep impurity region so that an effective sectional area for charge transfer increases to ensure high charge transfer efficiency, in comparison to the channel of the conventional structure.

Second, because the depleted p-type impurity region 50 remains between the photodiode and the transfer transistor (i.e., between the n-type impurity region 46 for the photodiode and the floating source region 48), the potential barrier of the depleted p-type impurity region 50 is modulated by light to generate a signal gain. The signal gain significantly serves to increase the signal-to-noise ratio (SNR) of the image sensor. In the conventional structure shown in FIG. 2, since the p-type impurity region is disposed under the thick gate electrode 13, light is hardly transmitted through the p-type impurity region. Also, the channel is so shallow that only a very slight portion reacts to light, thus the modulation of the potential barrier due to light rarely occurs. In contrast to the conventional structure, the structure of the present invention easily reacts to light because not only the depleted p-type impurity region 50 but also the photodiode are completely exposed to light and the floating source region 48 is formed to a relative great depth.

Third, as shown in FIG. 6, the area of the photodiode according to the present invention is slightly reduced compared to the conventional structure owing to the depleted p-type impurity region 50 disposed between the floating source region 48 of the transfer transistor and the photodiode. However, the floating source region 48 and the depleted p-type impurity region 50 are portions that substantially react to light to generate a signal gain. Accordingly, in the case of structural optimization, the effective area of the photodiode can be increased. As a result, according to the present invention, the sensitivity of the photodiode is not degraded.

Fourth, according to the present invention, the floating source region 48 or the n-type impurity region 49 can be concurrently formed during the formation of the floating drain region 45 of the transfer transistor. Accordingly, the present invention requires no additional mask or no additional ion implantation process.

As explained thus far, according to the present invention, a floating source region is formed between an n-type impurity region for a photodiode and a gate electrode, and an additional n-type impurity region is formed between the n-type impurity region for the photodiode and the floating source region. Thus, both charge transfer efficiency and a signal gain can be enhanced. Also, a variance in characteristics among pixels and wafers is effectively reduced to improve the performance of an image sensor. Further, neither mask nor process operation is added, thus increasing yield.

Although exemplary embodiments of the present invention have been described with reference to the attached drawings, the present invention is not limited to these embodiments, and it should be appreciated to those skilled in the art that a variety of modifications and changes can be made without departing from the spirit and scope of the present invention.

What is claimed is:

1. A CMOS image sensor comprising:
a substrate;
a gate electrode disposed on the substrate and electrically isolated from the substrate by a gate insulating layer;
a first floating region disposed in the substrate of one side of the gate electrode;
a first impurity region for a photodiode disposed in the substrate of the other side of the gate electrode;
a second floating region disposed in the substrate between the first impurity region for the photodiode and the gate electrode; and
a second impurity region for the photodiode disposed in a surface portion of the substrate including the first impurity region for the photodiode and the second floating region.

2. The CMOS image sensor according to claim 1, wherein the first impurity region for the photodiode is spaced a predetermined distance apart from the second floating region.

3. The CMOS image sensor according to claim 1, wherein the first and second floating regions are doped with impurities of the same conductivity type.

4. The CMOS image sensor according to claim 1, wherein the first impurity region for the photodiode and the second impurity region for the photodiode are doped with impurities of different conductivity types from each other.

5. The CMOS image sensor according to claim 1, further comprising a third impurity region disposed in the substrate between the first impurity region for the photodiode and the second floating region.

6. The CMOS image sensor according to claim 5, wherein the third impurity region is disposed in a lateral surface of the first impurity region for the photodiode.

7. The CMOS image sensor according to claim 5, wherein the third impurity region has a depth equal to the second floating region.

8. The CMOS image sensor according to claim 5, wherein the third impurity region is doped with impurities of the same conductivity type as the first impurity region for the photodiode.
